(19) United States
(12) Patent Application Publication
(10) Pub. No.: US 2005/0238964 A1
(43) Pub. Date: Oct. 27, 2005

(54) PHOTOMASK

(76) Inventors: Chao-Yung Chu, Taipei Hsien (TW); Wen-Bin Hsieh, Hsin-Chu Hsien (TW); Te-Yang Fang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/709,276

(22) Filed: Apr. 26, 2004

(51) Int. Cl. B44F 1/00; G03F 9/00; G03C 5/00; A47G 1/12

(52) U.S. Cl. 430/5; 428/14; 355/53

(57) ABSTRACT

A photomask includes a substrate having a transparent substrate, a mask pattern positioned on a surface of the transparent substrate, a transparent electrostatic discharge (ESD) ring positioned on the surface of the transparent substrate and surrounding the mask pattern, a pellicle covering over the mask pattern, and a mounting adhesive used for sticking the pellicle on the transparent electrostatic discharge ring. The transparent electrostatic discharge ring is utilized to examine a binding condition between the pellicle and the transparent substrate and to suppress an electrostatic discharge.

### BACKGROUND OF INVENTION

1. Field of the Invention

The present invention relates to a photomask, and more specifically, to a photomask having a pellicle adhering to a transparent electrostatic discharge (ESD) ring, which is utilized to examine a binding condition between the pellicle and a transparent substrate and to suppress an electrostatic discharge.

2. Description of the Prior Art

Photomasks play an important role in forming integrated circuits on a semiconductor wafer. For forming desired integrated circuits on the semiconductor wafer, a plurality of photomasks is made and mask patterns designed according to layouts of the desired integrated circuits are formed on each photomask. Then, a photolithographic process is used to transfer the mask patterns onto a photoresist layer on the semiconductor wafer. In order to form desired integrated circuits exactly, the mask patterns must be made precisely. Accordingly, it is an important issue to fabricate a photomask having accurate mask patterns.

Pease refer to FIG. 1 and FIG. 2. FIG. 1 is a top view of a conventional photomask. FIG. 2 is a sectional view along line 2-2 of the photomask shown in FIG. 1. As shown in FIG. 1 and FIG. 2, a photomask 10 comprises a transparent quartz substrate 12, whose surface includes a mask pattern region 12a. Additionally, the photomask 10 further includes a mask pattern 14 formed on the mask pattern region 12a, a chromium film 16 formed on the substrate 12 and surrounding the mask pattern 14, and a ring-shaped transparent region 18 located in the chromium film 16. The mask pattern 14 is a layout having a plurality of transparent regions and opaque regions. When a photolithographic process is performed, the mask pattern 14 is transferred onto a photoresist layer on a semiconductor substrate, while the opaque chromium film 16 functions to obstruct unnecessary light beams. In addition, the ring-shaped transparent region 18 does not comprise any metals and it functions as an insulating electrostatic discharge (ESD) ring for isolating the mask pattern 14 from the chromium film 16. Due to the ESD ring 18, the static electricity on the chromium film 16 cannot be transferred to the mask pattern 14, thereby avoiding an electrostatic discharge occurring in the mask pattern 14. It should be noted that if the electrostatic discharge occurs in the mask pattern 14, a pattern transferred through the photomask 10 would lose its clarity or the mask pattern 14 might be destroyed.

The photomask 10 further comprises a pellicle 20 capped over the mask pattern 14 for avoiding contaminants, such as dust, sticking to the mask pattern 14. The pellicle 20 usually has a transparent film 22, a frame 24 adhering to the transparent film 22 for supporting the transparent film 22, and a mounting adhesive 26 for sticking the frame 24 on the substrate 12. It is important that the mounting adhesive 26 should be completely stuck on the substrate 12 so that the mask pattern 14 would not be polluted by contaminants. If a width of the mounting adhesive 26 is too narrow, or there are gaps or bubbles between the mounting adhesive 26 and the substrate 12, airstreams will carry contaminants or glue residues into the space between the pellicle 20 and substrate 12. Unfortunately, the contaminants or the glue residues will adhere to the mask pattern 14, which leads to reducing the reliability of following photolithographic processes. For example, as a particle stays on one of the transparent regions of the mask pattern 14, an undesired pattern of the particle may be transferred to a photoresist layer on a wafer when a photolithographic process is performed, which results in forming a wrong pattern in the photoresist layer on the wafer.

However, as shown in FIG. 1, because the mounting adhesive 26 of the pellicle 20 is located on the opaque chromium film 16, gaps or any other defects existing between the mounting adhesive 26 and the substrate 12 cannot be detected before a photolithographic process is performed. Accordingly, the photomask 10 having the above-mentioned defects always brings about lots of unrecoverable problems in semiconductor products, thus reducing yields of products and increasing production costs.

### SUMMARY OF INVENTION

It is therefore one object of the claimed invention to provide a photomask to solve the above-mentioned problem.

According to the claimed invention, a photomask is provided. The photomask comprises a transparent substrate, a mask pattern positioned on a surface of the transparent substrate, a transparent electrostatic discharge (ESD) ring positioned on the surface of the transparent substrate and surrounding the mask pattern, a pellicle covering over the mask pattern, and a mounting adhesive positioned between the pellicle and the transparent electrostatic discharge ring for sticking the pellicle on the transparent electrostatic discharge ring. The transparent electrostatic discharge ring is utilized to examine a binding condition between the pellicle and the transparent substrate and to suppress an electrostatic discharge.

It is an advantage over the prior art that the claimed invention makes the mounting adhesive adhere to the ring-shaped transparent region. The ring-shaped transparent region functions as an ESD ring to suppress the electrostatic discharge. Furthermore, the binding condition between the mounting adhesive and the substrate can be inspected through the ring-shaped transparent region, thereby ensuring that contaminants cannot enter the space between the pellicle and the substrate to pollute the mask pattern. Accordingly, the reliability of a photolithographic process and yields of products can be effectively improved.

These and other objects of the present invention will be apparent to those of ordinary skill in the art after having read the following detailed description of the preferred embodiment that is illustrated in the various figures and drawings.

### BRIEF DESCRIPTION OF DRAWINGS

FIG. 1 is a top view of a conventional photomask.

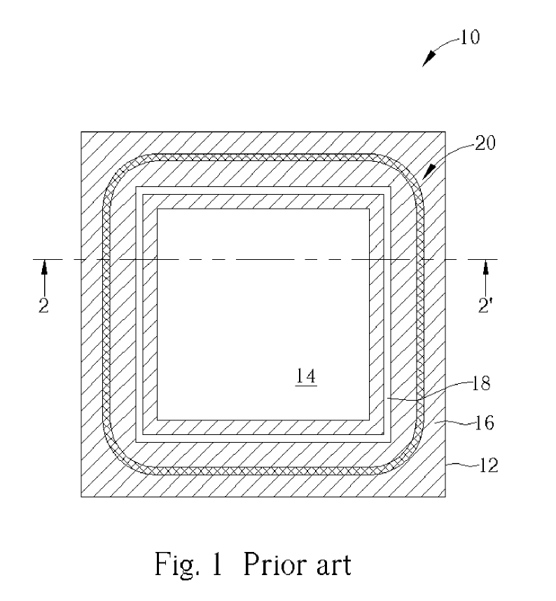

FIG. 2 is a sectional view along line 2-2 of the photomask shown in FIG. 1.

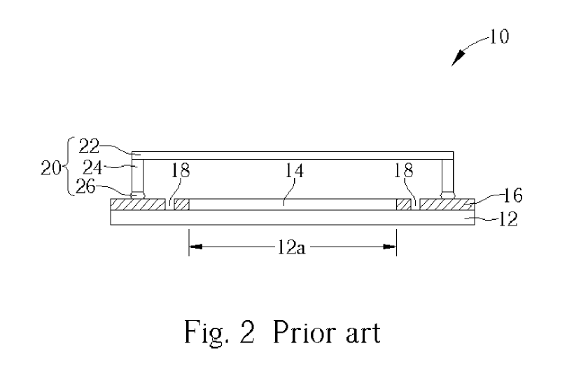

FIG. 3 is a top view of a photomask according to the preferred embodiment of the present invention.

FIG. 4 is a sectional view along line 4-4 of the photomask shown in FIG. 3.

### DETAILED DESCRIPTION

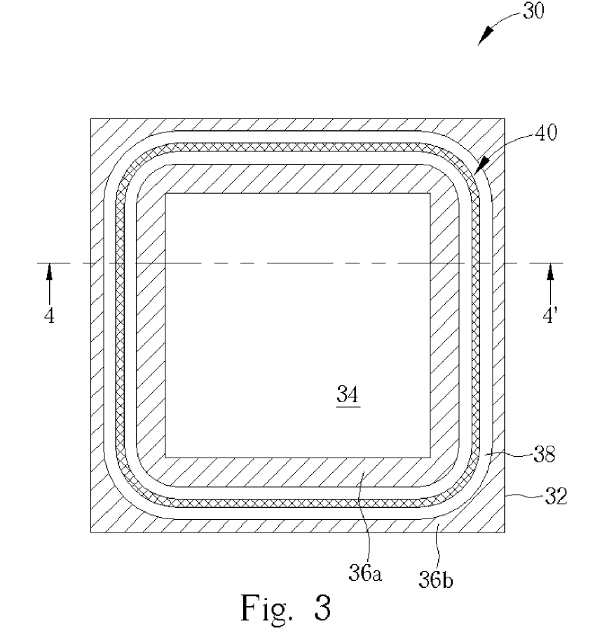

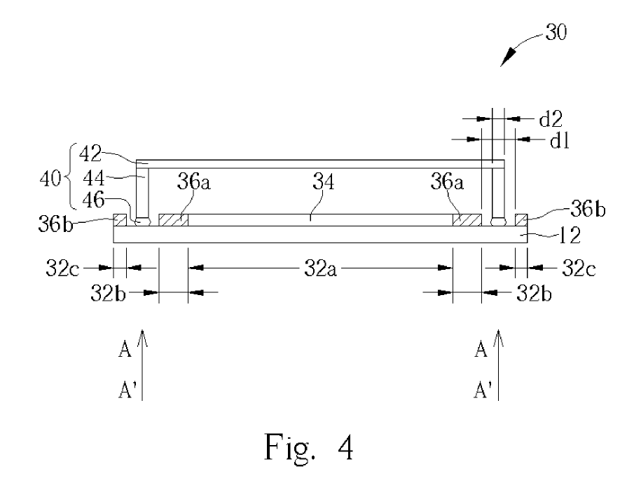

Pease refer to FIG. 3 and FIG. 4. FIG. 3 is a top view of a photomask according to the preferred embodiment of the present invention. FIG. 4 is a sectional view along line 4-4 of the photomask shown in FIG. 3. As shown in FIG. 3 and FIG. 4, a photomask 30 comprises a substrate 32, which is usually composed of an insulating and highly pervious to light material, such as quartz. A surface of the photomask 30 includes a mask pattern region 32a, an inner region 32b surrounding the mask pattern region 32a, and an outer region 32c surrounding the inner region 32b. Additionally, the photomask 30 further includes a mask pattern 34 formed on the mask pattern region 32a, a chromium film 36a formed on the inner region 32b, a chromium film 36b formed on the outer region 32c, and a ring-shaped transparent region 38 located between the chromium film 36a and the chromium film 36b. The mask pattern 34 is a layout having a plurality of transparent regions, semiopaque regions, opaque regions, or phase shifting regions. When a photolithographic process is performed, the mask pattern 34 is transferred onto a photoresist layer on a semiconductor substrate, while the opaque chromium films 36a and 36b function to obstruct unnecessary light beams. The ring-shaped transparent region 38 does not comprise any metals and it functions as an insulating ESD ring for avoiding an electrostatic discharge occurring in the mask pattern 34. Furthermore, the mask pattern 34, the chromium films 36a and 36b, and the ring-shaped transparent region 38 can be formed simultaneously. That is, a chromium layer is deposited on the substrate 32 initially. Then, an etching process is performed to etch the chromium layer so as to concurrently form the mask pattern 34, the chromium films 36a and 36b, and the ring-shaped transparent region 38.

As shown in FIG. 4, the photomask 30 further comprises a pellicle 40 capped over the mask pattern 34 for avoiding contaminants, such as dust, being absorbed by the mask pattern 34. The pellicle 40 has a transparent film 42, a frame 44 adhering to the transparent film 42 for supporting the transparent film 42, and a mounting adhesive 46 for fixing the frame 44 to the substrate 32. The transparent film 42 is composed of a highly pervious to light material, such as nitrocellulose or fluoropolymer, and the frame 44 is an aluminum frame that is treated with anodic treatment for preventing the frame 44 from reflecting light beams. The mounting adhesive 46 is formed on the frame 44 and is used to fix the frame 44 to the ring-shaped transparent region 38 so that the pellicle 40 can cover the whole mask pattern 34. A width d of the ring-shaped transparent region 38 should be larger than a width d₂ of the frame 44, and therefore, the mounting adhesive 46 can adhere to a surface of the ring-shaped transparent region 38. According to the preferred embodiment of the present invention, d₁ is approximately equal to 3 mm, and d₂ is around 2 mm. Furthermore, d₁ and d₂ can be modified according to process requirements in another embodiment of the present invention.

Moreover, when the fabrication of the photomask 40 is completed or a regular inspection is performed on the photomask 40, a binding condition between the mounting adhesive 46 and the substrate 32 can be examined by operators or machines, such as an optical microscope, through the ring-shaped transparent region 38. The following description will explain how to inspect the binding condition between the mounting adhesive 46 and the substrate 32 in the present invention. As shown in FIG. 4, because the mounting adhesive 46 adheres to the surface of the ring-shaped transparent region 38, operators or machines can inspect the mounting adhesive 46 for defects through the ring-shaped transparent region 38. That is, as operators or machines look along the arrow AA, they can observe the binding condition between the mounting adhesive 46 and the substrate 32. If the mounting adhesive 46 adheres to the substrate 32 quite well, the photomask 40 can be used in a photolithographic process. Conversely, if there are gaps, bubbles, or any other defects between the mounting adhesive 46 and the substrate 32, the pellicle 40 should be separated from the substrate 32, followed by fixing a new pellicle 40 to the substrate 32. Finally, operators or machines inspect the mounting adhesive 46 for defects through the ring-shaped transparent region 38 again. The above-mentioned steps are repeated until the mounting adhesive 46 adheres to the substrate 32 without any defects.

In comparison with the prior art, the present invention makes the mounting adhesive 46 of the pellicle 40 adhere to the ring-shaped transparent region 38. The ring-shaped transparent region 38 functions as an ESD ring to avoid an electrostatic discharge occurring in the mask pattern 34. Furthermore, the ring-shaped transparent region 38 can be used to examine whether there are defects between the mounting adhesive 46 and the substrate 32, thereby ensuring that contaminants cannot enter the space between the pellicle 40 and the substrate 32 to pollute the mask pattern 34. As a result, the reliability of a photolithographic process and yields of products can be effectively improved.

Those skilled in the art will readily observe that numerous modifications and alterations of the device may be made while retaining the teachings of the invention. Accordingly, the above disclosure should be construed as limited only by the metes and bound of the appended claims.

1. A photomask comprising:
a transparent substrate;
a mask pattern positioned on a surface of the transparent substrate;
a transparent electrostatic discharge (ESD) ring positioned on the surface of the transparent substrate and surrounding the mask pattern;
a pellicle covering over the mask pattern; and
a mounting adhesive positioned between the pellicle and the transparent electrostatic discharge ring for sticking the pellicle on the transparent electrostatic discharge ring;
wherein the transparent electrostatic discharge ring is utilized to examine a binding condition between the pellicle and the transparent substrate and to suppress an electrostatic discharge.

2. The photomask of claim 1 wherein the pellicle comprises:
a transparent film; and
a frame having a first surface adhering to the transparent film and a second surface adhering to the mounting adhesive.

3. The photomask of claim 2 wherein the transparent film comprises nitrocellulose (NC) or fluoropolymer.

4. The photomask of claim 2 wherein the frame is an aluminum frame that is treated with anodic treatment for preventing the aluminum frame from reflecting light beams.

5. The photomask of claim 1 further comprising a first opaque chromium film positioned on the surface of the transparent substrate and located between the mask pattern and the electrostatic discharge ring.

6. The photomask of claim 5 further comprising a second opaque chromium film positioned on the surface of the transparent substrate and surrounding the electrostatic discharge ring.

7. A photomask comprising:
a substrate, a surface of the substrate having a mask pattern region and a ring-shaped transparent region surrounding the mask pattern region; and
a pellicle adhering to the ring-shaped transparent region and covering over the mask pattern region;
wherein the ring-shaped transparent region is utilized to examine a binding condition between the pellicle and the substrate.

8. The photomask of claim 7 wherein the ring-shaped transparent region is an electrostatic discharge ring utilized for suppressing an electrostatic discharge.

9. The photomask of claim 7 wherein the pellicle comprises:
a frame having a first surface and a second surface;
a transparent film positioned on the first surface of the frame; and
a mounting adhesive positioned on the second surface of the frame for sticking the pellicle on the ring-shaped transparent region.

10. The photomask of claim 9 wherein the transparent film comprises nitrocellulose or fluoropolymer.

11. The photomask of claim 9 wherein the frame is an aluminum frame that is treated with anodic treatment for preventing the aluminum frame from reflecting light beams.

12. The photomask of claim 7 wherein the surface of the substrate further comprises an inner region located between the mask pattern region and the ring-shaped transparent region.

13. The photomask of claim 12 wherein the surface of the substrate further comprises an outer region surrounding the ring-shaped transparent region.

14. The photomask of claim 13 further comprising a first opaque chromium film positioned on the inner region and a second opaque chromium film positioned on the outer region.

15. The photomask of claim 7 further comprising a mask pattern positioned on the mask pattern region.
